(19) United States
(12) Patent Application Publication
(10) Pub. No.: US 2024/0375865 A1
(43) Pub. Date: Nov. 14, 2024

(54) Article Transport Facility

(71) Applicant: Daifuku Co., Ltd., Osaka-shi (JP)

(72) Inventors: Yuya Hirao, Hinocho (JP); Daisuke Ogawa, Hinocho (JP)

(21) Appl. No.: 18/660,357

(22) Filed: May 10, 2024

(30) Foreign Application Priority Data
May 11, 2023 (JP) 2023-078651

(51) Int. Cl. B65G 1/04

(52) U.S. Cl. CPC B65G 1/0457; B65G 2201/0297

(57) ABSTRACT

An article transport facility includes a transport vehicle. The transport vehicle is configured to switch an access point of a connection destination while moving along a path and communicate with a control device. The control device transmits movement path information indicating a movement path along which the transport vehicle moves, and switching position information indicating switching positions at which the transport vehicle moving along the movement path performs switching of the access point, to the transport vehicle.

### CROSS-REFERENCE TO RELATED APPLICATION

This application claims priority to Japanese Patent Application No. 2023-078651 filed May 11, 2023, the disclosure of which is hereby incorporated by reference in its entirety.

### BACKGROUND OF THE INVENTION

### 1. Field of the Invention

The present invention relates to an article transport facility including a transport vehicle configured to move along a prescribed path to transport an article, a control device configured to control the transport vehicle, and a plurality of access points, each of which configured to perform wireless communication with the transport vehicle.

### 2. Description of Related Art

An example of such an article transport facility is disclosed in Japanese Patent Application Laid-Open No. 2011-166671. In the following, reference numerals shown in parentheses in the description of the related art are those of Japanese Patent Application Laid-Open No. 2011-166671.

In the facility disclosed in Japanese Patent Application Laid-Open No. 2011-166671, control devices (18 and 20) such as servers and a plurality of transport vehicles (12) are configured to be connected to each other via a wireless LAN to communicate with each other. Communication between the control devices (18 and 20) and the transport vehicles (12) is performed via access points (8). In this facility, a traveling route of the transport vehicle (12) is divided in areas (10) for each of the plurality of access points (8). The transport vehicle (12) stores a map showing these areas (10), and is configured to switch the access point (8) of a connection destination when approaching a boundary of the area (10). Accordingly, the transport vehicle (12) travels while sequentially making a connection to the access points (8) of the areas (10) into which itself enters.

However, a communication intensity between the transport vehicle (12) and the access point (8) is likely to be affected by a movement direction of the transport vehicle (12), a reception range of radio waves by a wireless communication device mounted on the transport vehicle (12), and the like. Therefore, in a configuration in which switching of the access point (8) is performed based on the areas (10) simply divided for each of the plurality of access points (8), that is, in an aspect in which a switching position of the access point (8) is determined by the area (10), a communication state between the control devices (18 and 20) and the transport vehicle (12) may not be satisfactorily maintained.

### SUMMARY OF THE INVENTION

In view of the above circumstances, there is a demand for realizing an article transport facility capable of favorably maintaining a communication state between a control device and a moving transport vehicle.

Techniques for solving the above problems are as follows.

An article transport facility including a transport vehicle configured to move along a prescribed path to transport an article; a control device configured to control the transport vehicle; and a plurality of access points, each of which configured to perform wireless communication with the transport vehicle, in which the transport vehicle is configured to switch the access points of connection destinations while moving along the path and communicate with the control device, and the control device transmits movement path information indicating a movement path along which the transport vehicle moves, and switching position information indicating switching positions at which the transport vehicle moving along the movement path performs switching of the access points, to the transport vehicle.

According to the present configuration, the transport vehicle is able to receive the movement path information and the switching position information from the control device. The movement path information is information indicating the movement path along which the transport vehicle moves, and the switching position information is information indicating the switching position at which the transport vehicle performs switching of the access points while moving along the designated movement path. Since this switching position is set based on the movement path of the transport vehicle, for example, a movement direction of the transport vehicle, a reception range of radio waves by the moving transport vehicle, and the like may be considered. Therefore, it is possible to set the switching position of the access point to an appropriate position in accordance with a situation. In a configuration in which the access point is switched based on the area divided for each of the plurality of access points as in the related art, the transport vehicle may exit the area immediately after entering the area depending on the movement direction of the transport vehicle, or the like, and in this case, the access point may be unnecessarily switched. However, according to the present configuration, the switching position of the access point is able to be flexibly set in accordance with the traveling direction of each transport vehicle regardless of the area, and the access point is able to be switched at an appropriate timing for the moving transport vehicle. Therefore, according to the present configuration, it is possible to maintain a good communication state between the control device and the transport vehicle even during the movement of the transport vehicle.

Further features and advantages of the technique according to the present disclosure will be apparent from the following exemplary and non-limiting description with reference to the accompanying drawings.

### BRIEF DESCRIPTION OF THE DRAWINGS

FIG. 1 is a plan view of an article transport facility;

FIG. 2 is a control block diagram;

FIG. 3 is a conceptual diagram showing a communication configuration;

FIG. 4 is a diagram showing various pieces of information transmitted from a control device to a transport vehicle;

FIG. 5 is a correspondence table between each of points and access points to be connected at each of the points in a path; and

FIG. 6 is a relative distance table showing a relative distance between each of the access points and each of the points on the path.

### DESCRIPTION OF THE INVENTION

Hereinafter, embodiments of an article transport facility will be described with reference to the drawings.

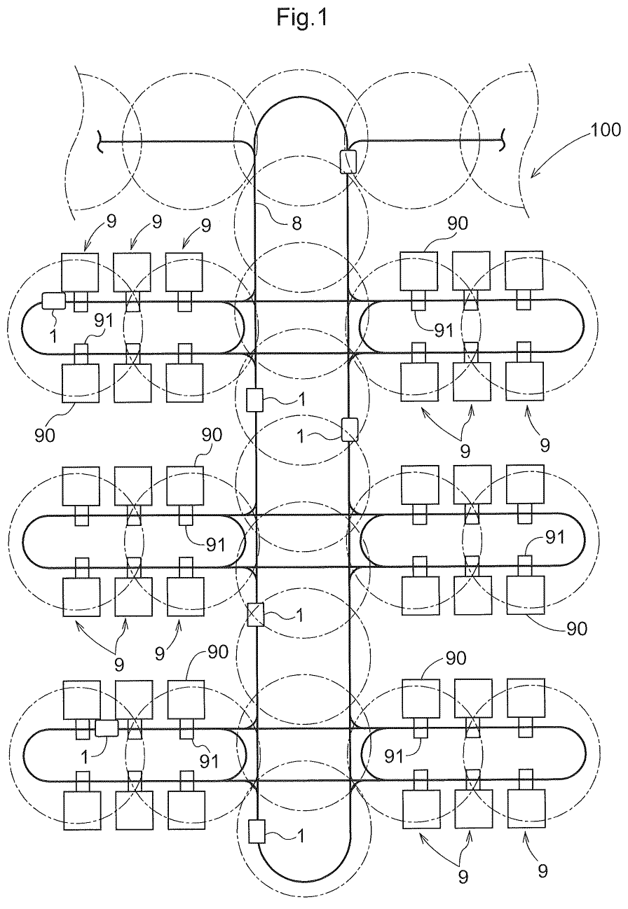

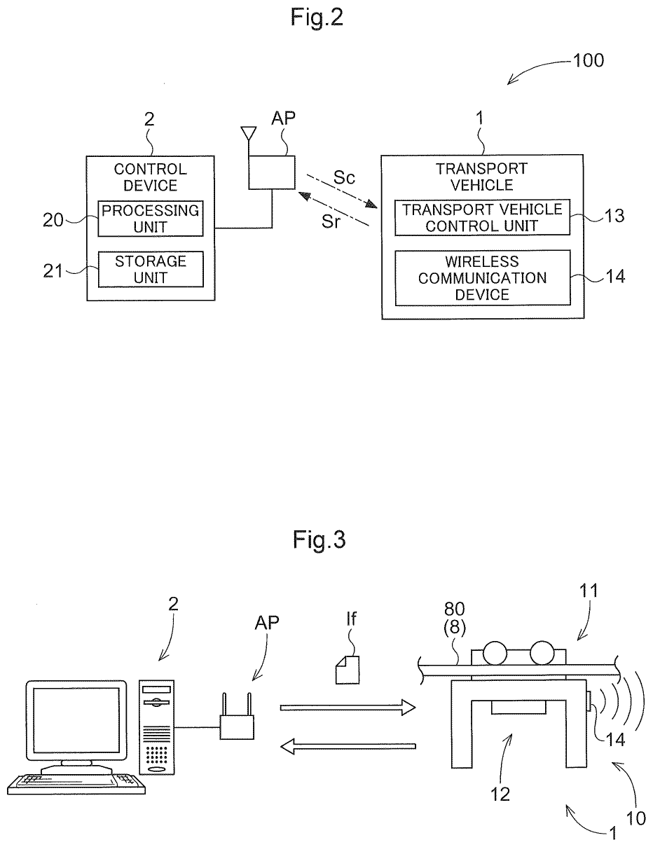

As shown in FIG. 1, an article transport facility 100 includes transport vehicles 1 that move along a prescribed path 8 to transport articles (not shown), and a control device 2 (see FIG. 2 and the like) that controls the transport vehicles 1.

As shown in FIG. 3, in the present embodiment, the path 8 is configured by using a rail 80 installed near a ceiling. The transport vehicle 1 is configured as a so-called ceiling transport vehicle that travels while being supported by the rail 80. In the present embodiment, the transport vehicle 1 includes a body 10, a traveling portion 11 that travels along the rail 80, and a holder 12 that holds the article. The body 10 is configured to be capable of accommodating the holder 12 and the article held by the holder 12.

As shown in FIG. 1, in the present embodiment, the article transport facility 100 includes a plurality of transfer target locations 9 provided along the path 8. The transfer target location 9 is disposed below the path 8. In the present example, the path 8 includes an inter-bay and a plurality of intra-bays connected to the inter-bay. The plurality of transfer target locations 9 are provided in each intra-bay. The inter-bay is able to be referred to as a movement area in which the transport vehicle 1 mainly moves. The intra-bay is able to be referred to as a transfer area in which the transport vehicle 1 mainly performs a transferring operation of the article. The transport vehicle 1 is configured to transfer the article with the transfer target locations 9 by lifting and lowering the holder 12 (see FIG. 3).

In the present embodiment, the article transport facility 100 includes a plurality of transport vehicles 1. Each of the plurality of transport vehicles 1 is configured to receive a transport command from the control device 2 (see FIG. 2 and the like) and execute a task in accordance with the transport command. For example, the transport command includes information on a transport source and a transport destination of the article. The transport vehicle 1 that receives the transport command transports the article from the transport source to the transport destination. The transport source and the transport destination include the transfer target locations 9.

The articles handled by the article transport facility 100 are various. In the present example, the article transport facility 100 is used in a semiconductor manufacturing factory. Therefore, a substrate accommodating container (so-called front opening unified pod (FOUP)) that accommodates a substrate (a wafer, a panel, or the like), a reticle accommodating container (so-called reticle pod) that accommodates a reticle, and the like are the articles. In this case, the transport vehicle 1 transports the article, such as the substrate accommodating container or the reticle accommodating container, along the path 8 between respective steps.

In the present embodiment, the transfer target location 9 includes a processing device 90 that performs processing on the article and a transfer table 91 that is disposed adjacent to the processing device 90. In the present specification, the “processing on the article” means processing on an accommodated article (substrate or reticle) accommodated in the article as the accommodating container. The transport vehicle 1 receives the article on which the processing by the processing device 90 is finished from the transfer table 91 or delivers the article on which the processing by the processing device 90 is not finished to the transfer table 91. The processing device 90 performs, for example, various processing such as thin film formation, photolithography, and etching.

As shown in FIG. 2, the article transport facility 100 includes a plurality of access points AP (only one access point AP is shown in FIG. 2) that performs wireless communication with the transport vehicle 1, respectively. The access point AP is disposed at a center of each of a plurality of circular ranges shown in FIG. 1. These circular ranges indicate a guideline of a communicable range of each access point AP. However, this is only the guideline, and communication may be possible even outside the circular range.

The control device 2 and the transport vehicle 1 are configured to be communicable with each other in both directions via any of the plurality of access points AP. The transport vehicle 1 is configured to switch the access point AP of the connection destination while moving along the path 8 and communicate with the control device 2.

In the present embodiment, the control device 2 is configured to repeatedly transmit a confirmation signal Sc to the transport vehicle 1 at a set cycle. The transport vehicle 1 is configured to transmit a reception signal Sr to the control device 2 in accordance with receiving of the confirmation signal Sc. With such a configuration, the control device 2 is able to periodically confirm a communication state with the transport vehicle 1.

In the present embodiment, the control device 2 includes a processing unit 20 and a storage unit 21. The processing unit 20 is configured by using, for example, an arithmetic processing device such as a central processing unit (CPU). The storage unit 21 is configured by using, for example, a storage device such as a random access memory (RAM) or a read only memory (ROM) that is able to be referred to by an arithmetic processing device. Then, each functional unit of the control device 2 functions by software (program) stored in the storage unit 21 or hardware such as an arithmetic circuit provided separately, or both thereof. The processing unit 20 provided in the control device 2 is operated as a computer that executes each program.

In the present embodiment, the transport vehicle 1 includes a transport vehicle control unit 13. The transport vehicle control unit 13 is configured by using, for example, an arithmetic processing device such as a central processing unit (CPU).

In the present embodiment, the transport vehicle 1 includes a wireless communication device 14 that performs communication with the access point AP. In the present example, the wireless communication device 14 is configured to communicate with each of the plurality of access points AP in a wireless manner, and each of the plurality of access points AP is configured to communicate with the control device 2 in a wired manner. That is, the wireless communication device 14 is configured to be communicable with the control device 2 via any of the plurality of access points AP. As shown in FIG. 3, in the present embodiment, the wireless communication device 14 is installed in a front portion of the transport vehicle 1. Specifically, the wireless communication device 14 is installed in a front portion of the body 10 of the transport vehicle 1. Accordingly, it is easy to make the reception range of the radio waves of the wireless communication device 14 widen toward the traveling direction of the transport vehicle 1.

As shown in FIG. 3, the control device 2 is connected to an operation terminal. An operator is able to input various commands to the control device 2 by operating the operation terminal, and is also able to refer to a control situation by using the operation terminal.

The access point AP is configured by using a wireless access point device. The access point AP is configured to emit wireless radio waves. A communication intensity between the access point AP and the transport vehicle 1 is represented by a received signal strength indicator (RSSI). The unit is, for example, decibel milliwatt (dBm).

The control device 2 is configured to transmit various pieces of information If to the transport vehicle 1 via the access point AP. The transport vehicle 1 moves along the path 8 based on the information If received from the control device 2.

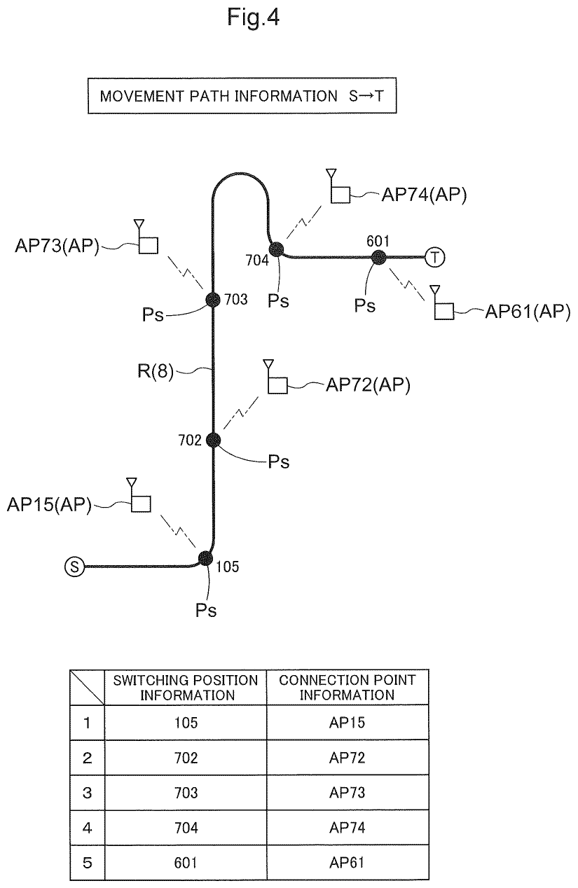

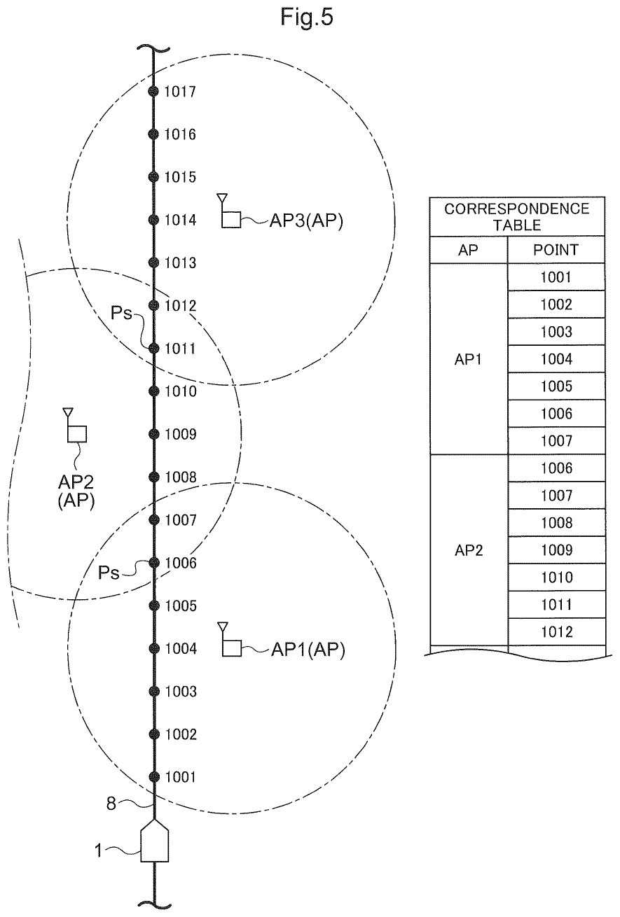

As shown in FIG. 4, the control device 2 transmits movement path information indicating the movement path R along which the transport vehicle 1 moves, and switching position information indicating the switching position Ps at which the transport vehicle 1 moving along the movement path R performs switching of the access point AP, to the transport vehicle 1. That is, the “various pieces of information If” transmitted from the control device 2 to the transport vehicles 1 include at least the movement path information and the switching position information.

In the present embodiment, the movement path R from a departure point S designated for the transport vehicle 1 to an arrival point T is shown in the movement path information. The movement path information shows an address of each point along the movement path R. The movement path information indicates the traveling direction to be traveled at a branch point of the path 8.

Although detailed illustration is omitted, a plurality of information holding bodies holding the address information is installed at intervals along an extension direction of the path 8. In addition, the information holding body is installed at the departure point S and the arrival point T, and at a branch point or a merging point of the path 8. Each information holding body holds address information on a point where the information holding body is installed. The transport vehicle 1 includes a reading device that reads address information from the information holding body, and travels along the path 8 while reading the address information on each information holding body. For example, a one-dimensional code or a two-dimensional code is able to be used as the information holding body, and a one-dimensional code reader or a two-dimensional code reader is able to be used as the reading device.

In the present embodiment, the switching position Ps is indicated by using the address of each point in the movement path R. In the present example, the switching position information includes information on all the switching positions Ps in the movement path R. That is, in the present example, the information on all the switching positions Ps in the movement path R is transmitted from the control device 2 to the transport vehicle 1 together with the movement path information. In the example shown in FIG. 4, an address 105, an address 702, an address 703, an address 704, and an address 601, each of which is set as the switching position Ps, are included in the switching position information. The transport vehicle 1 switches the access point AP at each of the address 105, the address 702, the address 703, the address 704, and the address 601.

In the present embodiment, the control device 2 further transmits connection point information indicating the plurality of access points AP that has to be sequentially connected by the transport vehicle 1 moving along the movement path R, to the transport vehicle 1. That is, in the present embodiment, the “various pieces of information If” transmitted from the control device 2 to the transport vehicle 1 include the connection point information in addition to the movement path information and the switching position information.

In the present embodiment, the access point AP to be connected at each switching position Ps are determined based on the traveling direction of the transport vehicle 1 in the movement path R. The access point AP present in front of the switching position Ps is set as the access point AP to be connected at the switching position Ps, with the traveling direction of the transport vehicle 1 as a reference. In a case in which the plurality of access points AP are present in front of the switching position Ps, the access point AP closest to the switching position Ps among the plurality of access points AP present in front of the switching position Ps may be set as the access point AP to be connected at the switching position Ps.

As described above, in the present embodiment, the wireless communication device 14 is installed in the front portion of the transport vehicle 1 in order to widen the reception range of the radio waves in the traveling direction of the transport vehicle 1. Therefore, as in the present embodiment, when the access point AP to be connected is present at the switching position Ps in front of the switching position Ps, that is, in front of the transport vehicle 1 that has reached the switching position Ps, the transport vehicle 1 that moves while searching for the access point AP in a range in front of itself is able to easily perform the connection to the access point AP in a smooth manner.

The switching position information and the connection point information are transmitted while being associated with each other. That is, the switching position Ps indicated by the address and the access point AP to be connected at the switching position Ps are associated with each other. In the example shown in FIG. 4, it is indicated as information that the switching is performed to the access point AP15 at the address 105 as the switching position Ps. Similarly, switching to the access point AP72 at the address 702, switching to the access point AP73 at the address 703, switching to the access point AP74 at the address 704, and switching to the access point AP61 at the address 601 are shown as information, respectively. The transport vehicle 1 is connected to the access point AP set for each address at each address in accordance with these pieces of information.

In this way, the transport vehicle 1 that receives the movement path information and the switching position information from the control device 2, in the present embodiment, the transport vehicle 1 that receives the connection point information in addition to these pieces of information, moves along the movement path R while repeating the switching of the access point AP.

In the present embodiment, in a case in which the movement path R is changed while the transport vehicle 1 is moving, the control device 2 transmits the movement path information indicating a new movement path R after the change and the switching position information indicating the information on the switching position Ps corresponding to the new movement path R, to the transport vehicle 1. The control device 2 changes the movement path R, for example, in accordance with a situation of the path 8 that changes over time due to traffic jams or the like. In this way, even in a case in which the movement path R of the transport vehicle 1 is changed during movement, the movement path information and the switching position information are created by the control device 2 based on the new movement path R after the change, and these pieces of information are transmitted to the transport vehicle 1. In the present embodiment, in a case in which the movement path R is changed while the transport vehicle 1 is moving, the control device 2 transmits the connection point information corresponding to the new movement path R in addition to the movement path information and the switching position information, to the transport vehicle 1.

Next, the selection of the access point AP to be connected at each point will be described. The selection is performed by the control device 2, and the selected access point AP is transmitted to the transport vehicle 1 as the connection point information.

As shown in FIG. 5, in the present embodiment, the control device 2 holds a correspondence table between each point in the path 8 and the access point AP to be connected at each point as data. The control device 2 creates the switching position information and the connection point information by referring to the correspondence table, and transmits these pieces of information to the transport vehicle 1.

FIG. 5 shows examples of each of points of addresses 1001 to 1017 in the path 8. In addition, the first access point AP1, the second access point AP2, and the third access point AP3 are disposed along the path 8 so as to be adjacent to each other. Each of the points of the addresses 1001 to 1017 is included in any of the communication range of the first access point AP1, the communication range of the second access point AP2, and the communication range of the third access point AP3.

For example, each of the points of the addresses 1001 to 1007 is included in the communication range of the first access point AP1. In other words, in a state of being at each point of the addresses 1001 to 1007, the transport vehicle 1 is able to be connected to the first access point AP1. In addition, each point of the addresses 1006 to 1012 is included in the communication range by the second access point AP2. In other words, in a state of being at each point of the addresses 1006 to 1012, the transport vehicle 1 is able to be connected to the second access point AP2.

The communication ranges of the first access point AP1 and the second access point AP2 overlap with each other. In the example shown in FIG. 5, the communication range of the first access point AP1 and the communication range of the second access point AP2 overlap with each other at each point of the address 1006 and the address 1007. That is, at each point of the address 1006 and the address 1007, the transport vehicle 1 is able to be connected to both the first access point AP1 and the second access point AP2.

As described above, in the present embodiment, the access point AP to be connected at each switching position Ps is determined based on the traveling direction of the transport vehicle 1 in the movement path R. As in the example shown in FIG. 5, in a case in which the transport vehicle 1 moves from the address 1001 to the address 1007, the connection destination is switched from the first access point AP1 to the second access point AP2. In this case, the control device 2 selects the connection destination, to which the transport vehicle 1 is to be connected, to the second access point AP2 at the point of the address 1006 to which both the first access point AP1 and the second access point AP2 are able to be connected. That is, in this case, the point of the address 1006 is set as the switching position Ps, and the access point AP to be connected at the switching position Ps is set as the second access point AP2. Similarly, in the case of the example shown in FIG. 5, the point of the address 1011 is set as the next switching position Ps, and the access point AP to be connected at the switching position Ps is set as the third access point AP3.

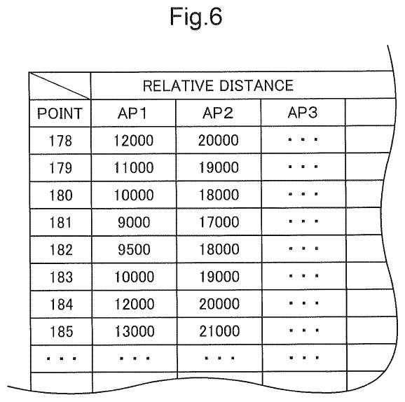

As described above, in the present embodiment, the control device 2 creates the switching position information and the connection point information based on the correspondence table between each point in the path 8 and the access point AP to be connected at each point. However, instead of such a correspondence table or in addition to the correspondence table, the control device 2 may create the switching position information and the connection point information based on a relative distance table (see FIG. 6) showing a relative distance between each access point AP and each point in the path 8. In this case, at each point through which the transport vehicle 1 that moves along the movement path R passes, the access point AP closest thereto is selected as the access point AP to which the transport vehicle 1 is to be connected, by the control device 2.

### OTHER EMBODIMENTS

Next, other embodiments will be described.
(1) In the embodiment described above, the example is described in which the control device 2 transmits, to the transport vehicle 1, the connection point information indicating the plurality of access points AP at which the transport vehicle 1 moving along the movement path R has to be sequentially connected, in addition to the movement path information and the switching position information. However, the present invention is not limited to such an example, and the control device 2 may not transmit the connection point information to the transport vehicle 1. In this case, the transport vehicle 1 may search for and determine the access point AP to be connected by itself at the switching position Ps or its vicinity.
(2) In the embodiment described above, the example is described in which the access point AP present in front of the switching position Ps is set as the access point AP to be connected at the switching position Ps, with the traveling direction of the transport vehicle 1 as a reference. However, the present invention is not limited to such an example, and the access point AP present at any position around the switching position Ps may be set as the access point AP to be connected at the switching position Ps. For example, the access point AP closest to the switching position Ps in a range of 360° around the switching position Ps may be set as the access point AP to be connected.
(3) In the embodiment described above, the example is described in which the wireless communication device 14 is installed in the front portion of the transport vehicle 1. However, the present invention is not limited to such an example, and the wireless communication device 14 may be set in any part of the transport vehicle 1. For example, the wireless communication device 14 may be installed in a rear portion of the transport vehicle 1.
(4) In the embodiment described above, the example is described in which the switching position information includes information on all the switching positions Ps in the movement path R. However, the present disclosure is not limited to such an example, and the switching position information may include only information on some of the switching positions Ps among all the switching positions Ps in the movement path R. In this case, the control device 2 may transmit the information on all the switching positions Ps in the movement path R to the transport vehicle 1 by transmitting the switching position information to the transport vehicle 1 a plurality of times.
(5) In the embodiment described above, the example is described in which the path 8 is configured by using the rail 80 installed near the ceiling, and the transport vehicle 1 is configured as the ceiling transport vehicle that travels while being supported by the rail 80. However, the present invention is not limited to such an example, and the transport vehicle 1 may be configured as a floor surface transport vehicle that travels on a floor surface. In this case, the path 8 may be configured by using a magnetic tape or the like provided along the floor surface, or may be virtually set along the floor surface.
(6) In addition, the configuration disclosed in the embodiment described above is able to be applied in combination with configurations disclosed in other embodiments as long as there is no contradiction. The embodiments disclosed in the present specification are merely exemplary in all respects with regard to other configurations. Therefore, various modifications are able to be made within a range not departing from the scope of the present disclosure.

### Summary of Present Embodiment

A summary of the present embodiment will be described below.

An article transport facility including a transport vehicle configured to move along a prescribed path to transport an article; a control device configured to control the transport vehicle; and a plurality of access points, each of which configured to perform wireless communication with the transport vehicle, in which the transport vehicle is configured to switch the access points of connection destinations while moving along the path and communicate with the control device, and the control device transmits movement path information indicating a movement path along which the transport vehicle moves, and switching position information indicating switching positions at which the transport vehicle moving along the movement path performs switching of the access points, to the transport vehicle.

According to the present configuration, the transport vehicle is able to receive the movement path information and the switching position information from the control device. The movement path information is information indicating the movement path along which the transport vehicle moves, and the switching position information is information indicating the switching position at which the transport vehicle performs switching of the access points while moving along the designated movement path. Since this switching position is set based on the movement path of the transport vehicle, for example, a movement direction of the transport vehicle, a reception range of radio waves by the moving transport vehicle, and the like may be considered. Therefore, it is possible to set the switching position of the access point to an appropriate position in accordance with a situation. Therefore, according to the present configuration, it is possible to maintain a good communication state between the control device and the transport vehicle even during the movement of the transport vehicle.

It is preferable that the switching position information includes information on all the switching positions in the movement path.

According to the present configuration, it is possible to maintain a good communication state between the control device and the transport vehicle at least from the start of the movement of the transport vehicle in the designated movement path to the end of the movement.

It is preferable that the control device further transmits the connection point information indicating the plurality of access points to which the transport vehicle moving along the movement path is sequentially connected, to the transport vehicle.

According to the present configuration, it is possible to instruct the transport vehicle which access point to connect to at each point in the movement path. Therefore, according to the present configuration, it is easier to maintain a more favorable communication state between the control device and the transport vehicle moving along the movement path.

It is preferable that the control device transmits, to the transport vehicle, the movement path information indicating a new movement path after the change, and the switching position information indicating information on the switching position corresponding to the new movement path, in a case in which the movement path is changed during movement of the transport vehicle.

According to the present configuration, even in a case in which the movement path of the transport vehicle is changed during movement, the movement path information and the switching position information are created based on the new movement path after the change, and the information is transmitted to the transport vehicle. Therefore, according to the present configuration, even in a case in which the movement path of the transport vehicle is changed, it is possible to maintain a good communication state between the control device and the transport vehicle.

### INDUSTRIAL APPLICABILITY

The technique according to the present disclosure is able to be used for an article transport facility including transport vehicles that move along a prescribed path to transport articles, a control device that controls the transport vehicle, and a plurality of access points that performs wireless communication with the transport vehicle, respectively.

What is claimed is:

1. An article transport facility, comprising:
a transport vehicle configured to move along a prescribed path to transport an article;
a control device configured to control the transport vehicle; and
a plurality of access points, each of which configured to perform wireless communication with the transport vehicle,
wherein the transport vehicle is configured to switch the access points of connection destinations while moving along the path and communicate with the control device, and
wherein the control device transmits movement path information indicating a movement path along which the transport vehicle moves, and switching position information indicating switching positions at which the transport vehicle moving along the movement path performs switching of the access points, to the transport vehicle.

2. The article transport facility according to claim 1, wherein the switching position information includes information on all the switching positions in the movement path.

3. The article transport facility according to claim 1, wherein the control device further transmits connection point information indicating the plurality of the access points to which the transport vehicle moving along the movement path is sequentially connected, to the transport vehicle.

4. The article transport facility according to claim 1, wherein the control device transmits, when the movement path is changed while the transport vehicle moves, the movement path information indicating a new movement path after the change and the switching position information indicating information on the switching positions corresponding to the new movement path, to the transport vehicle.

5. The article transport facility according to claim 2, wherein the control device further transmits connection point information indicating the plurality of the access points to which the transport vehicle moving along the movement path is sequentially connected, to the transport vehicle.

6. The article transport facility according to claim 2, wherein the control device transmits, when the movement path is changed while the transport vehicle moves, the movement path information indicating a new movement path after the change and the switching position information indicating information on the switching positions corresponding to the new movement path, to the transport vehicle.
